(19) United States
(12) Patent Application Publication
(10) Pub. No.: US 2024/0262084 A1
(43) Pub. Date: Aug. 8, 2024

(54) SILICON CARBIDE SEED CRYSTAL

(71) Applicant: GlobalWafers Co., Ltd., Hsinchu (TW)

(72) Inventors: Ray-Hua Horng, Hsinchu (TW); Tsung-Po Chuang, Hsinchu (TW); Chai-Wei Ku, Hsinchu (TW); Ying-Ru Shih, Hsinchu (TW)

(73) Assignee: GlobalWafers Co., Ltd., Hsinchu (TW)

(21) Appl. No.: 18/429,457

(22) Filed: Feb. 1, 2024

Related U.S. Application Data
(60) Provisional application No. 63/443,026, filed on Feb. 2, 2023.

(30) Foreign Application Priority Data
Jan. 22, 2024 (TW) 113102367

(51) Int. Cl. B32B 18/00; B32B 7/12

(52) U.S. Cl. CPC B32B 18/00; B32B 7/12; B32B 2250/02; B32B 2255/205; B32B 2255/28; B32B 2307/7376; C04B 2237/12; C04B 2237/365

(57) ABSTRACT

A silicon carbide seed crystal includes a first silicon carbide substrate, a second silicon carbide substrate, a metal layer, and a first adhesion layer. The first silicon carbide substrate has a carbon surface and a silicon surface opposite to each other; the second silicon carbide substrate has a carbon surface and a silicon surface opposite to each other, in which the carbon surface of the second silicon carbide substrate is a surface utilized for crystal growth. The metal layer is disposed between the silicon surface of the second silicon carbide substrate and the silicon surface of the first silicon carbide substrate, and the first adhesion layer is disposed between the silicon surface of the first silicon carbide substrate and the metal layer, in which a material of the first adhesion layer has a property of easily forming silicide with silicon.

### CROSS-REFERENCE TO RELATED APPLICATION

This application claims the priority benefits of U.S. provisional application Ser. No. 63/443,026, filed on Feb. 2, 2023, and Taiwan application serial no. 113102367, filed on Jan. 22, 2024. The entirety of each of the above-mentioned patent applications is hereby incorporated by reference herein and made a part of this specification.

### BACKGROUND

### Technical Field

The disclosure relates to a semiconductor seed crystal, and in particular to a silicon carbide seed crystal utilized for growing silicon carbide crystals.

### Description of Related Art

Silicon carbide is currently the key material for power electronics, and the manufacturing of silicon carbide substrates requires first forming a silicon carbide crystal and then slicing the silicon carbide crystal. Silicon carbide crystals are generally manufactured in crystal growth furnace environments of ultra-high temperature and ultra-high pressure, and the growth rate thereof is slow, so the cost is high. Moreover, the manufacturing process requires the use of high-quality silicon carbide seed crystal, which is one-time consumable, resulting in high costs.

### SUMMARY

The disclosure provides a silicon carbide seed crystal, which can reduce the cost of seed crystals while still growing high-quality silicon carbide crystals.

The silicon carbide seed crystal according to the disclosure includes a first silicon carbide substrate, a second silicon carbide substrate, a metal layer, and a first adhesion layer. The first silicon carbide substrate has a carbon surface and a silicon surface opposite to each other; the second silicon carbide substrate has a carbon surface and a silicon surface opposite to each other, in which the carbon surface of the second silicon carbide substrate is a surface utilized for crystal growth. The metal layer is disposed between the silicon surface of the second silicon carbide substrate and the silicon surface of the first silicon carbide substrate, and the first adhesion layer is disposed between the silicon surface of the first silicon carbide substrate and the metal layer, in which the material of the first adhesion layer has a property of easily forming silicide with silicon.

In an embodiment of the disclosure, the first adhesion layer is in direct contact with the silicon surface of the first silicon carbide substrate.

In an embodiment of the disclosure, the material of the first adhesion layer includes titanium, tantalum, chromium, or a combination thereof.

In an embodiment of the disclosure, the silicon carbide seed crystal may further include a second adhesion layer disposed between the silicon surface of the second silicon carbide substrate and the metal layer, in which the material of the second adhesion layer has a property of easily forming silicide with silicon.

In an embodiment of the disclosure, impurities of the second silicon carbide substrate are less than impurities of the first silicon carbide substrate.

In an embodiment of the disclosure, impurities of the second silicon carbide substrate are less than 1 ppm, a micropipe density (MPD) is less than 1 cm⁻², a basal plane dislocation (BPD) is less than 500 cm⁻², and a threading screw dislocation (TSD) is less than 100 cm⁻².

In an embodiment of the disclosure, the silicon carbide seed crystal may further include an alloy layer formed between the metal layer and the second silicon carbide substrate after undergoing a high-temperature process, in which the alloy layer includes carbon, silicon, and metal.

In an embodiment of the disclosure, the bow and warp of the silicon carbide seed crystal are both less than 20 μm.

In an embodiment of the disclosure, the total thickness of the silicon carbide seed crystal is greater than 500 μm.

In an embodiment of the disclosure, the thickness of the metal layer is less than 100 nm.

In an embodiment of the disclosure, the material of the metal layer has a property of easily diffusing and reacting with silicon carbide.

In an embodiment of the disclosure, the material of the metal layer includes silver, aluminum, gold, or a combination thereof.

In an embodiment of the disclosure, the metal layer is in direct contact with the silicon surface of the second silicon carbide substrate.

In an embodiment of the disclosure, the thickness of the first adhesion layer is less than 10 nm.

Based on the above, the disclosure combines two silicon carbide substrates as the silicon carbide seed crystal through a specific interface structure. Since the interface structure has the adhesion layer that is easy to form silicide with silicon and the metal layer that is easy to diffuse and react with silicon carbide, a secondary silicon carbide substrate may be used to bond with a high-quality silicon carbide substrate, so as to reduce the cost of seed crystal. Also, the carbon surface of the high-quality silicon carbide substrate among the two silicon carbide substrates is utilized for crystal growth, thereby a high-quality silicon carbide crystal can be grown.

In order to make the above features of the disclosure more comprehensible, embodiments are given below and described in detail with reference to the accompanying drawings.

### BRIEF DESCRIPTION OF THE DRAWINGS

FIG. 1 is a schematic cross-sectional view of a silicon carbide seed crystal according to an embodiment of the disclosure.

FIG. 2 is a schematic cross-sectional view of the silicon carbide seed crystal according to another embodiment of the disclosure.

FIG. 3A to FIG. 3D are schematic cross-sectional views of a manufacturing process of the silicon carbide seed crystal according to some embodiments of the disclosure.

FIG. 4 is a schematic view of using the silicon carbide seed crystal according to some embodiments of the disclosure to grow silicon carbide crystal.

FIG. 5 is a schematic cross-sectional view of the silicon carbide seed crystal after undergoing a high-temperature process according to some embodiments of the disclosure.

### DESCRIPTION OF THE EMBODIMENTS

The following description provides various embodiments for implementing different features of the disclosure. Further, the embodiments are merely illustrative and are not intended to limit the scope and application of the disclosure. Furthermore, the relative dimensions (for example, length or thickness) and relative positions of regions or structural components may be reduced or enlarged for clarity. In addition, similar or identical reference numerals used in different drawings represent similar or identical components or features.

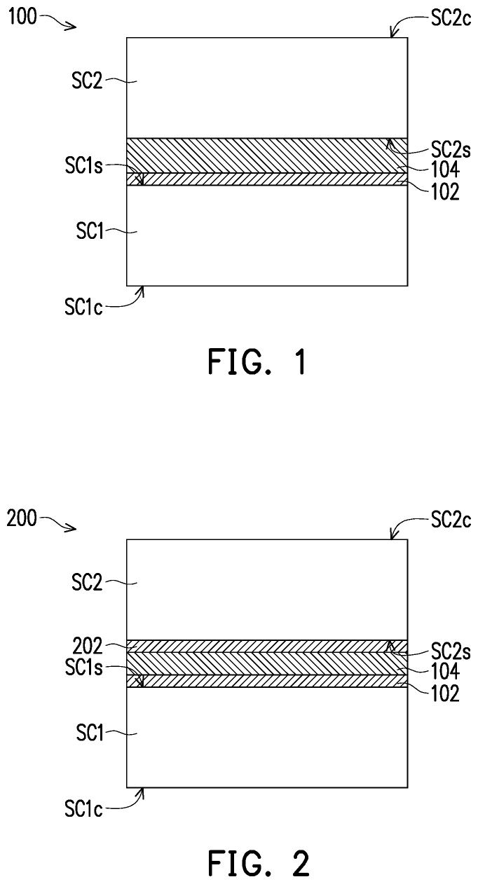

FIG. 1 is a schematic cross-sectional view of a silicon carbide seed crystal according to an embodiment of the disclosure. As shown in FIG. 1, a silicon carbide seed crystal 100 includes a first silicon carbide substrate SC1, a second silicon carbide substrate SC2, a metal layer 104, and a first adhesion layer 102. The first silicon carbide substrate SC1 has a carbon surface SC1c and a silicon surface SC1s opposite to each other; the second silicon carbide substrate SC2 also has a carbon surface SC2c and a silicon surface SC2s opposite to each other, in which the carbon surface SC2c of the second silicon carbide substrate SC2 is the surface utilized for crystal growth, so the exposed side of the second silicon carbide substrate SC2 is the carbon surface SC2c. The metal layer 104 is disposed between the silicon surface SC2s of the second silicon carbide substrate SC2 and the silicon surface SC1s of the first silicon carbide substrate SC1, and the first adhesion layer 102 is disposed between the silicon surface SC1s of the first silicon carbide substrate SC1 and the metal layer 104, so as to improve the adhesion between the first silicon carbide substrate SC1 and the second silicon carbide substrate SC2.

In this embodiment, the surface of the second silicon carbide substrate SC2 in contact with the metal layer 104 is the silicon surface SC2s, and the surface of the first silicon carbide substrate SC1 in contact with the first adhesion layer 102 is the silicon surface SC1s. Since the material of the first adhesion layer 102 has a property of easily forming silicide with silicon, the ultra-high temperature environment of the crystal growth furnace may be withstood, moreover, during the high-temperature crystal growth process, the first adhesion layer 102 first reacts with the silicon surface SC1s of the first silicon carbide substrate SC1 to form silicide, so the subsequently grown silicon carbide crystal is not contaminated or affected. For example, the material of the first adhesion layer 102 includes titanium (Ti), tantalum (Ta), chromium (Cr), or a combination thereof. Therefore, once the temperature of the process continues to rise, titanium silicide, tantalum silicide, chromium silicide, or a combination thereof is formed between the first adhesion layer 102 and the silicon carbide substrate SC1. In one embodiment, the thickness of the first adhesion layer 102 is less than 10 nm, such as less than 8 nm or less than 6 nm.

In FIG. 1, the thickness of the metal layer 104 may be less than 100 nm, such as in a range of 20 nm to 80 nm or 30 nm to 70 nm. In one embodiment, the material of the metal layer 104 has a property of easily diffusing and reacting with silicon carbide, such as silver, aluminum, gold, or a combination thereof. Therefore, once the temperature of the process continues to rise (for example, the crystal growth temperature of 700° C. or more), the metal layer 104 and the second silicon carbide substrate SC2 produce an alloy, such as carbon silicon silver alloy, carbon silicon aluminum alloy, or carbon silicon gold alloy, and the metal layer 104 does not volatilize and pollute the silicon carbide crystal growth cavity.

From the perspective of cost saving, the first silicon carbide substrate SC1 may use a secondary silicon carbide substrate with poor quality; in other words, the impurities of the second silicon carbide substrate SC2 are less than the impurities of the first silicon carbide substrate SC1. From the perspective of growing high-quality crystals, the impurities of the second silicon carbide substrate SC2 are, for example, less than 1 ppm, the micropipe density (MPD) is, for example, less than 1 cm⁻², the basal plane dislocation (BPD) is, for example, less than 500 cm⁻², and the threading screw dislocation (TSD) is, for example, less than 100 cm⁻². Since the second silicon carbide substrate SC2 has fewer defects, it is beneficial to growing high-quality silicon carbide crystal. In addition, if the bow and warp of the silicon carbide seed crystal 100 are less than 20 m, then it is beneficial to crystal growth. In one embodiment, the total thickness of the silicon carbide seed crystal 100 is greater than 500 km. Therefore, as long as the above conditions are met, the thickness of the second silicon carbide substrate SC2 may be adjusted, and a sufficiently thick first silicon carbide substrate SC1 may be used, so as to reduce the cost while providing high-quality silicon carbide seed crystal 100.

FIG. 2 is a schematic cross-sectional view of the silicon carbide seed crystal according to another embodiment of the disclosure, the same element symbols as those in the previous embodiment are used to represent the same or similar parts and components, and the relevant content of the same or similar parts and components can also be referred to the content of the previous embodiment, so no further description will be given.

In FIG. 2, the difference between a silicon carbide seed crystal 200 and the previous embodiment is that, a second adhesion layer 202 is disposed between the silicon surface SC2s of the second silicon carbide substrate SC2 and the metal layer 104. Therefore, both sides of the metal layer 104 are not in contact with the first silicon carbide substrate SC1 and the second silicon carbide substrate SC2, but are separated by the first adhesion layer 102 and the second adhesion layer 202. The materials of the first adhesion layer 102 and the second adhesion layer 202 both have the property of easily forming silicide with silicon, so the materials are helpful for the bonding between the metal layer 104 with respect to the first silicon carbide substrate SC1 and the second silicon carbide substrate SC2. Moreover, while the high temperature environment causes the oxygen of the native oxides of the first silicon carbide substrate SC1 and the second silicon carbide substrate SC2 to escape to the surface of the metal layer 104 to form metal oxide, the first adhesion layer 102 and the second adhesion layer 202 according to the embodiment may capture oxygen molecules, and thus preventing the bonding strength from decreasing. For example, the material of the second adhesion layer 202 includes titanium, tantalum, chromium, or a combination thereof. Therefore, once the temperature of the process continues to rise, titanium silicide, tantalum silicide, chromium silicide, or a combination thereof is formed between the second adhesion layer 202 and the silicon carbide substrate SC2. In one embodiment, the thickness of the second adhesion layer 202 is less than 10 nm, such as less than 8 nm or less than 6 nm.

In addition to the structure in the drawings, the silicon carbide seed crystal according to the disclosure may also be made of a three-layer silicon carbide substrate bonded to each other through the above-mentioned adhesion layer and metal layer, as long as the crystal growth surface is the carbon surface of the high-quality silicon carbide substrate. For other silicon carbide substrates, secondary silicon carbide substrates may be used to reduce seed crystal costs.

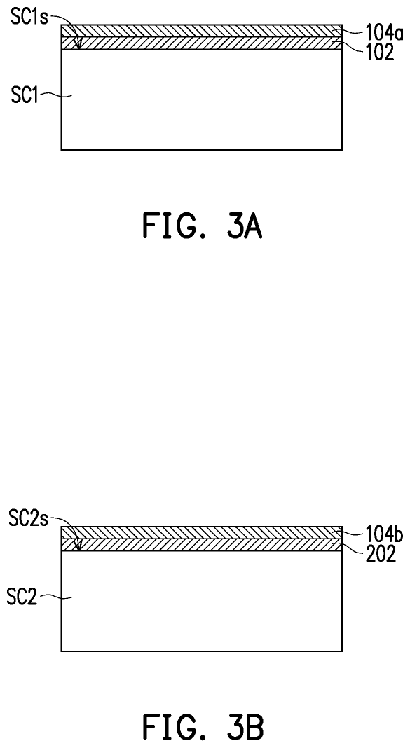

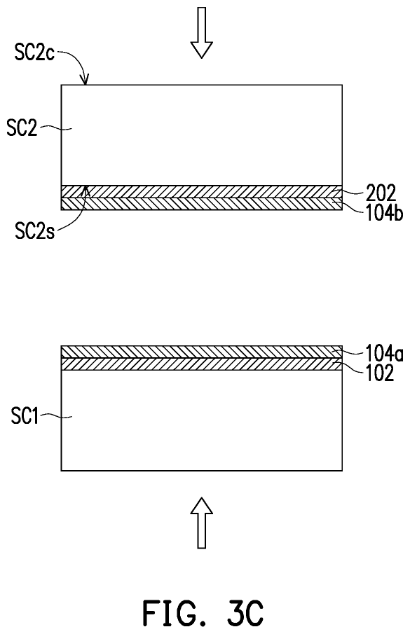

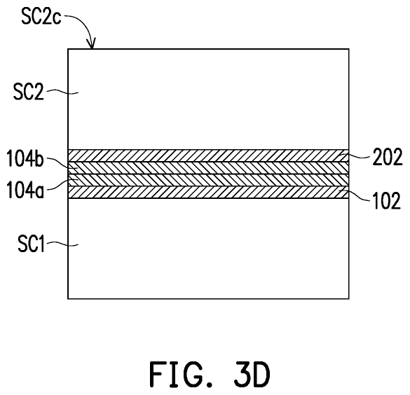

FIG. 3A to FIG. 3D are schematic cross-sectional views of a manufacturing process of the silicon carbide seed crystal according to some embodiments of the disclosure, in which the same reference numerals as in FIG. 2 are used to represent the same or similar parts and components, and for the relevant content of the same or similar parts and components, reference may be made to the content relevant to FIG. 2, so details will not be repeated here.

Please refer to FIG. 3A first. The first adhesion layer 102 and a metal layer 104a are formed on the silicon surface SC1s of the first silicon carbide substrate SC1, and a formation method thereof includes, for example, electron beam evaporation, sputtering, or thermal evaporation.

Then, referring to FIG. 3B, the second adhesion layer 202 and a metal layer 104b are formed on the silicon surface SC2s of the second silicon carbide substrate SC2, and a formation method thereof includes, for example, electron beam evaporation, sputtering, or thermal evaporation. In another embodiment, the second adhesion layer 202 may be omitted.

Next, please refer to FIG. 3C. A method of metal lamination is used to bond the metal layer 104a and the metal layer 104b, in which the metal bonding is performed, for example, with a bonding force of 1000 Kg to 5000 Kg, a process temperature of 150° C. to 400° C., and for 5 to 60 minutes. The above-mentioned high-temperature processing of metal bonding (150° C. to 400° C.) is beneficial to strengthening the bonding strength and allows the original oxygen in the first silicon carbide substrate SC1 and the second silicon carbide substrate SC2 to escape. However, the disclosure is not limited thereto, and the conditions for the process may be adjusted according to, for example, the material used or the thickness.

Finally, please refer to FIG. 3D. By bonding the metal layer 104a and the metal layer 104b, the first silicon carbide substrate SC1 and the second silicon carbide substrate SC2 may be bonded together, the first adhesion layer 102 between the metal layer 104a and the first silicon carbide substrate SC1 facilitates the bonding between the metal layer 104a and the first silicon carbide substrate SC1, and the second adhesion layer 202 between the metal layer 104b and the second silicon carbide substrate SC2 facilitates the bonding between the metal layer 104b and the second silicon carbide substrate SC2.

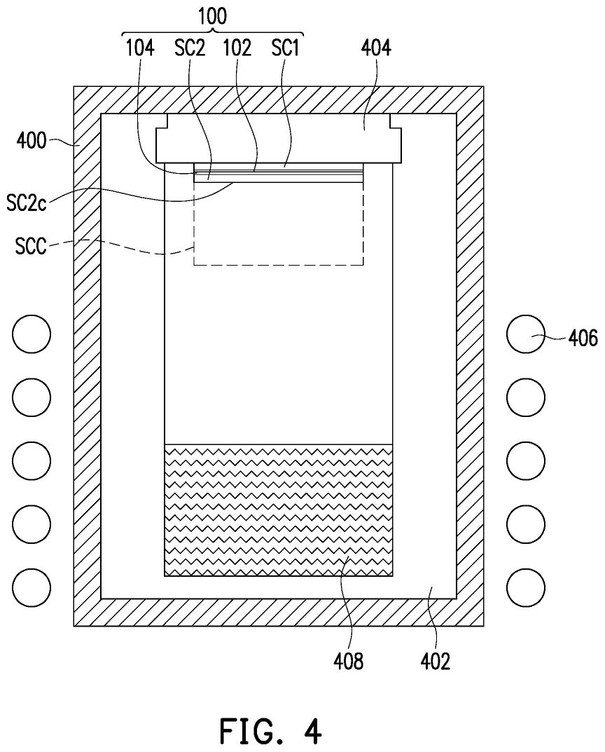

FIG. 4 is a schematic view of using the silicon carbide seed crystal according to some embodiments of the disclosure to grow silicon carbide crystal, in which the silicon carbide seed crystal 100 in FIG. 1 is taken as an example.

Please refer to FIG. 4. The equipment for growing silicon carbide crystal SCC may use a furnace 400 used in the PVT (Physical Vapor Transport) process. However, the equipment is not limited to the furnace 400 shown in FIG. 4, but all equipment and processes with the PVT-based growth mechanism may be used.

In the furnace 400 in FIG. 4, there is a bearing platform 404 on the top of a crucible 402, a silicon carbide raw material 408 is placed on the bottom of the crucible 402, and the carbon surface SC2c of the second silicon carbide substrate SC2 in the silicon carbide seed crystal 100 faces the silicon carbide raw material 408 as a surface utilized for crystal growth. An induction coil 406 is further disposed external to the crucible 402 for heating the silicon carbide raw material 408 in the crucible 402. When being heated and sublimated, the silicon carbide raw material 408 is driven by the temperature gradient to be transported to the growth surface (that is, the carbon surface SC2c) of the silicon carbide seed crystal 100 at a low temperature to nucleate and grow crystals, and the silicon carbide crystal SCC is formed.

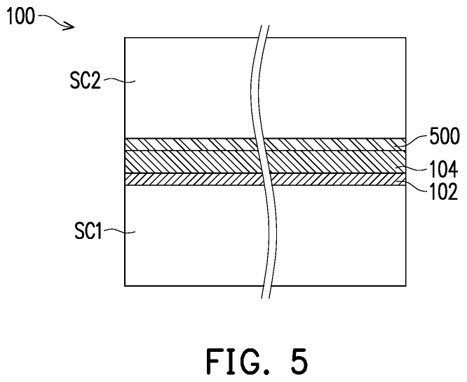

FIG. 5 is a schematic cross-sectional view of the silicon carbide seed crystal 100 in FIG. 4 after undergoing a high-temperature process (for example, a crystal growth process of 700° C. or more), in which an alloy layer 500 is formed between the metal layer 104 and the second silicon carbide substrate SC2. The alloy layer 500 comprises carbon, silicon, and metal, and the metal comprises in the alloy layer 500 is the metal in the metal layer 104. Therefore, when the material of the metal layer 104 is silver, aluminum, or gold, the alloy layer 500 is carbon silicon silver alloy, carbon silicon aluminum alloy, or carbon silicon gold alloy, so as to avoid the above-mentioned pollution and high-temperature metal volatilization problems.

The following experiments are described to verify the implementation effect of the disclosure, but the disclosure is not limited to the following content.

### Experimental Example 1

Firstly, a secondary first silicon carbide substrate and a high-quality second silicon carbide substrate are prepared. Please refer to the previous description regarding the quality of the silicon carbide substrate. The thickness of each silicon carbide substrate is 350 μm.

Using electron beam evaporation, the titanium (Ti) layer of the adhesion layer and the silver (Ag) layer of the metal layer are sequentially evaporated on the silicon surface of the first silicon carbide substrate and the silicon surface of the second silicon carbide substrate respectively, in which the thickness of the Ti layer as the adhesion layer is 5 nm, and the thickness of the Ag layer as the metal layer is 25 nm.

Afterward, the Ag layer of the metal layer on the second silicon carbide substrate is bonded to the Ag layer of the metal layer on the first silicon carbide substrate with a bonding force of 1500 kg and a temperature of 300° C. for 30 minutes.

### COMPARATIVE EXAMPLE

The same method as Experimental Example 1 is used for bonding, but merely the Ag layer is evaporated on the surface of the first silicon carbide substrate. The thicknesses are 25 nm, 50 nm, and 100 nm respectively, and there is no Ti layer.

### <Heat Treatment Test>

The samples of Experimental Example 1 and Comparative Example are respectively subjected to furnace tube annealing treatment at 900° C. for 30 minutes to simulate the crystal growth environment. Afterward, the annealed samples are observed, and it is found that the sample of Experimental Example 1 remains the same, but the sample of Comparative Example is separated into two substrates.

Therefore, the above test shows that the sample of Experimental Example 1 can withstand the high-temperature process. At the same time, based on the experimental result, it is speculated that in the comparative example, the silver layer between the substrates reacts with the oxygen in the furnace tube to form AgO, which affects the adhesion and caused the upper and lower silicon carbide substrates to separate. In contrast, Experimental Example 1 has the Ti layer that can capture oxygen molecules so that oxygen does not diffuse to the bonding surface or combine with silver. Although no experiments have been conducted on Ta and Cr, it should be known that Ta and Cr can also capture oxygen molecules so that oxygen does not diffuse to the bonding surface or combine with silver.

### Experimental Example 2

The same method as Experimental Example 1 is used for bonding, but the thickness of the Ag layer is changed to 50 nm.

### Experimental Example 3

The same method as Experimental Example 1 is used for bonding, but the thickness of the Ag layer is changed to 100 nm.

### <Tensile Test>

The samples of Experimental Example 1 to Experimental Example 3 are combined with a 3D printing mold using quick-drying glue. The 3D printing mold may clamp both ends of the tensile machine and then use the tensile machine to stretch outward at a fixed tensile speed (1 mm/sec), and the tensile strengths of the samples of Experimental Example 1 to Experimental Example 3 are obtained and recorded in Table 1 below.

TABLE 1

| | Experimental | | Experimental | | Experimental | |
|---|---|---|---|---|---|---|
| | Example 1 | | Example 2 | | Example 3 | |
| Ti/Ag (thickness) | 5 nm/25 nm | | 5 nm/50 nm | | 5 nm/100 nm | |
| tensile speed | 1 | mm/sec | 1 | mm/sec | 1 | mm/sec |
| tensile strength | 1.43 | MPa | >2.08 | MPa | 0.71 | MPa |

It may be seen from Table 1 that the silicon carbide seed crystals according to the disclosure all have good tensile strengths, especially the tensile strength of Experimental Example 2 is as high as 2.08 MPa.

In summary, in the silicon carbide seed crystal according to embodiments of the disclosure, since the interface structure has the adhesion layer that is easy to form silicide with silicon and the metal layer that is easy to diffuse and react with silicon carbide, a secondary silicon carbide substrate may be used to bond with a high-quality silicon carbide substrate, so as to reduce the cost of seed crystal and provide high-quality silicon carbide seed crystal.

Although the disclosure has been disclosed above in the embodiments, the embodiments are not intended to limit the disclosure. Persons with ordinary knowledge in the relevant technical field may make some changes and modifications without departing from the spirit and scope of the disclosure. Therefore, the protection scope of the disclosure shall be determined by the appended claims.

What is claimed is:

1. A silicon carbide seed crystal, comprising:
a first silicon carbide substrate, having a carbon surface and a silicon surface opposite to each other;
a second silicon carbide substrate, having a carbon surface and a silicon surface opposite to each other, wherein the carbon surface of the second silicon carbide substrate is a surface utilized for crystal growth;
a metal layer, disposed between the silicon surface of the second silicon carbide substrate and the silicon surface of the first silicon carbide substrate; and
a first adhesion layer, disposed between the silicon surface of the first silicon carbide substrate and the metal layer, wherein a material of the first adhesion layer has a property of easily forming silicide with silicon.

2. The silicon carbide seed crystal as claimed in claim 1, wherein the first adhesion layer is in direct contact with the silicon surface of the first silicon carbide substrate.

3. The silicon carbide seed crystal as claimed in claim 1, wherein the material of the first adhesion layer comprises titanium, tantalum, chromium, or a combination thereof.

4. The silicon carbide seed crystal as claimed in claim 1, further comprising a second adhesion layer disposed between the silicon surface of the second silicon carbide substrate and the metal layer, wherein a material of the second adhesion layer has a property of easily forming silicide with silicon.

5. The silicon carbide seed crystal as claimed in claim 1, wherein impurities of the second silicon carbide substrate are less than impurities of the first silicon carbide substrate.

6. The silicon carbide seed crystal as claimed in claim 1, wherein impurities of the second silicon carbide substrate are less than 1 ppm, a micropipe density (MPD) is less than 1 cm⁻², a basal plane dislocation (BPD) is less than 500 cm⁻², and a threading screw dislocation (TSD) is less than 100 cm⁻².

7. The silicon carbide seed crystal as claimed in claim 1, wherein a bow and a warp of the silicon carbide seed crystal are both less than 20 μm.

8. The silicon carbide seed crystal as claimed in claim 1, wherein a total thickness of the silicon carbide seed crystal is greater than 500 μm.

9. The silicon carbide seed crystal as claimed in claim 1, wherein a thickness of the metal layer is less than 100 nm.

10. The silicon carbide seed crystal as claimed in claim 1, wherein a material of the metal layer has a property of easily diffusing and reacting with silicon carbide.

11. The silicon carbide seed crystal as claimed in claim 1, wherein a material of the metal layer comprises silver, aluminum, gold, or a combination thereof.

12. The silicon carbide seed crystal as claimed in claim 1, further comprising an alloy layer formed between the metal layer and the second silicon carbide substrate after undergoing a high-temperature process, wherein the alloy layer comprises carbon, silicon, and metal.

13. The silicon carbide seed crystal as claimed in claim 1, wherein the metal layer is in direct contact with the silicon surface of the second silicon carbide substrate.

14. The silicon carbide seed crystal as claimed in claim 1, wherein a thickness of the first adhesion layer is less than 10 nm.
